(19) United States
(12) Patent Application Publication
(10) Pub. No.: US 2023/0108160 A1
(43) Pub. Date: Apr. 6, 2023

(54) LIGHT-EMITTING DEVICE AND METHOD FOR FORMING THE SAME AND LIGHT-EMITTING CIRCUIT

(71) Applicant: GaNrich Semiconductor Corporation, Hsinchu City (TW)

(72) Inventors: Chih-Hao CHEN, Hsinchu (TW); Chiao FU, Hsinchu (TW); Yi-Ru SHEN, Hsinchu (TW)

(21) Appl. No.: 17/955,024

(22) Filed: Sep. 28, 2022

(30) Foreign Application Priority Data
Oct. 4, 2021 (TW) 110136843

(51) Int. Cl. H01L 33/38; H01L 33/62; H01L 33/06; H01L 33/14; H01L 33/00

(52) U.S. Cl. CPC H01L 33/382; H01L 33/62; H01L 33/06; H01L 33/145; H01L 33/005; H01L 2933/0016; H01L 2933/0066

(57) ABSTRACT

A light-emitting device is provided. The light-emitting device includes a control part, a light-emitting part, a first electrode, and a second electrode. The control part includes a first semiconductor stack having a two-dimensional gas therein. The light-emitting part includes a second semiconductor stack. The first electrode electrically connects the control part and the light-emitting part. The second electrode electrically connects the control part and the light-emitting part. The control part and the light-emitting part are electrically connected in parallel through the first electrode and the second electrode.

### CROSS REFERENCE TO RELATED APPLICATIONS

This application claims priority of Taiwan Patent Application No. 110136843 filed on Oct. 4, 2021, the entirety of which is incorporated by reference herein.

### BACKGROUND

### Technical Field

The present disclosure relates to a light-emitting device, and in particular it relates to a light-emitting device including a high-electron mobility transistor (HEMT).

### Description of the Related Art

A light-emitting diode (LED) is a light-emitting element formed of a p-type semiconductor and an n-type semiconductor, which emits light through the combination of carriers on the P-N junction. The LED has advantages of small size, low power consumption, long lifetime, and fast response speed. As the size of light-emitting diodes becomes smaller and even down to microscopic scale, more opportunities for related applications have been brought. In addition to the display apparatus of conventional laptops and TVs, the above applications also include consumer electronic products, such as smart wearable devices, mobile phones, virtual reality headsets and the like.

Although existing light-emitting diodes have generally met their original intended purpose, they are not completely fulfilled every requirement in all aspects. The miniaturization of light-emitting diodes is also accompanied by deficiencies in the existing technologies and element structures of miniaturized products, such as mass transfer, driver integration, and signal control. The challenges in the upstream and downstream integration of driving and control modes of the miniaturized light-emitting diodes are more complex, and manufacturing the miniaturized light-emitting diodes may face increased cost for keeping high product yield.

### BRIEF SUMMARY

The present disclosure provides a light-emitting device. The light-emitting device includes a control part, a light-emitting part, a first electrode, and a second electrode. The control part includes a first semiconductor stack having a two-dimensional gas therein. The light-emitting part includes a second semiconductor stack. The first electrode electrically connects the control part and the light-emitting part. The second electrode electrically connects the control part and the light-emitting part. The control part and the light-emitting part are electrically connected in parallel through the first electrode and the second electrode.

The present disclosure provides a method for manufacturing a light-emitting device. The method includes providing a substrate with a first semiconductor stack and a second semiconductor stack sequentially formed thereon. The method further includes removing the second semiconductor stack on a first predetermined region. The method further includes forming a current blocking layer on the first predetermined region. The method further includes forming a second electrode on the first semiconductor stack and the second semiconductor stack. The second electrode electrically connects the first semiconductor stack and the second semiconductor stack. The method further includes removing the substrate. The method further includes removing the first semiconductor stack corresponding to a second predetermined region. The method further includes forming a first electrode on the first semiconductor stack and the second semiconductor stack. The first electrode electrically connects the first semiconductor stack and the second semiconductor stack. The first semiconductor stack and the second semiconductor stack are electrically connected in parallel through the first electrode and the second electrode.

The present disclosure provides a light-emitting circuit. The light-emitting circuit includes the aforementioned light-emitting device, a transistor, a resistor, and a diode. The transistor is coupled to the light-emitting device for accepting a driving signal. The transistor is selectively conducting according to the driving signal. The resistor is coupled between the light-emitting device and the transistor. The diode couples the light-emitting device and the resistor. The conduction direction of the diode is contrary to the conduction direction of the light-emitting part. The control part is conducting when the transistor is not conducting. The control part is not conducting when the transistor is conducting with a current passing through the light-emitting part and the resistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIGS. 1, 2, 3, 4, 5, 6, 7, 8, 9, 10, and 11 show cross-sectional views of a light-emitting device during the manufacturing process, in accordance with some embodiments of the present disclosure.

FIG. 12 shows a cross-sectional view of a light-emitting device in accordance with some embodiments of the present disclosure.

FIGS. 13A and 13B show schematic diagrams of an exemplary light-emitting circuit, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, and “substantially” used herein generally refer to a given value or a range within 20 percent, preferably within 10 percent, and more preferably within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

Unless otherwise defined, all terms (including technical and scientific terms) used herein have the same meaning as commonly understood by one of ordinary skill in the art to which this application belongs. It is to be understood that these terms, such as those defined in commonly used dictionaries, should be interpreted as having meanings consistent with the relevant art and the context or context of the present disclosure, and should not be interpreted in an idealized or overly formal manner, unless specifically defined in the examples of the present disclosure.

The present disclosure provides a light-emitting device and an exemplary light-emitting circuit including this light-emitting device. Considering that the light-emitting diode is driven by current, the manufacturing method of the light-emitting device of the present disclosure integrates the formation of a high electron mobility transistor into the manufacturing process of the light-emitting diode, and the driving mode of the light-emitting diode is controlled by the switching of the transistor. In addition, since the high electron mobility transistor is a high-speed transistor made of group III-V compounds, it is easily bonded with the light-emitting diode by bonding process and does not slow down the response speed of the light-emitting diode. As a result, compared with the conventional manufacturing process, which may result in poor yield due to the difference in precision when combining light-emitting diodes and transistors, the light-emitting device of the present disclosure can integrate the driving and the controlling elements with the light-emitting diodes via electrically-parallel connection. Thereby, while improving the efficiency of the light-emitting device, the yield of the light-emitting device is improved and the manufacturing cost thereof is reduced.

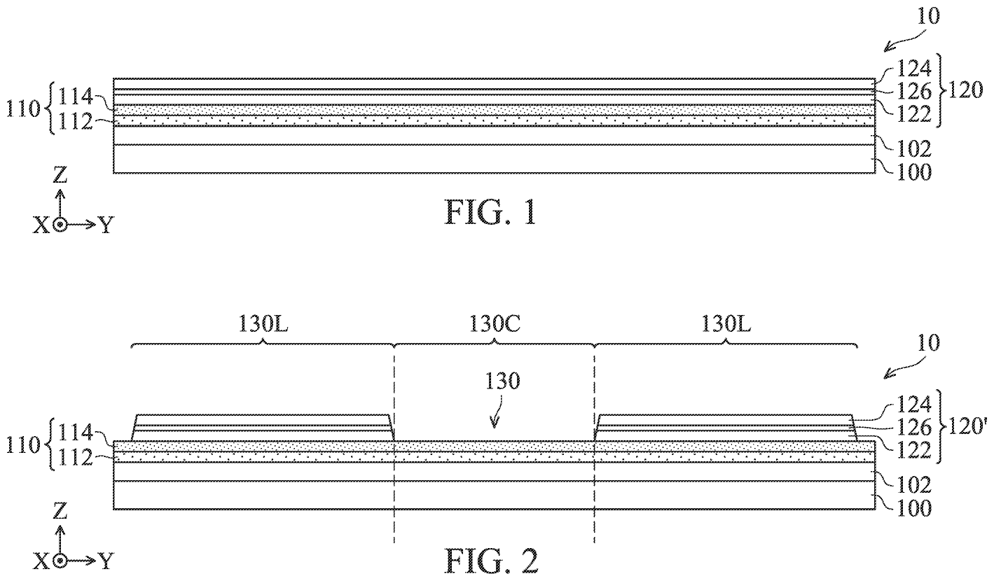

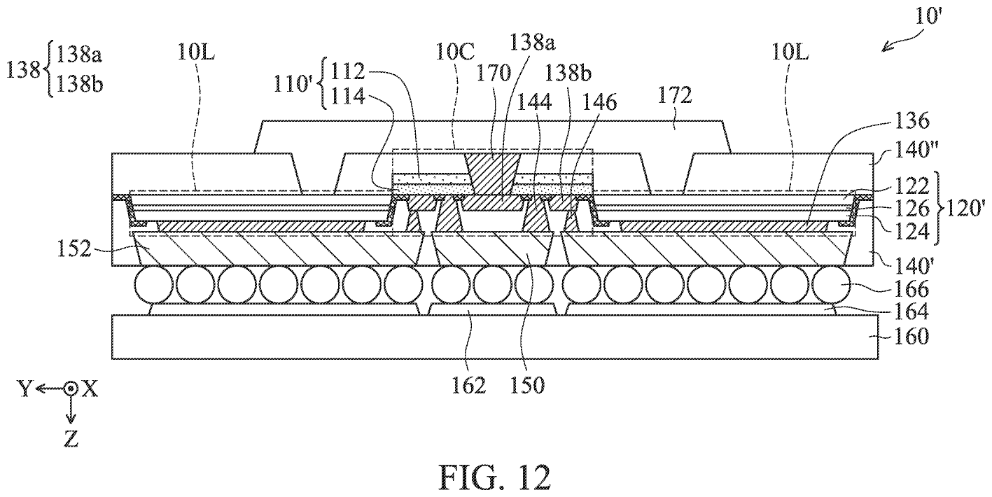

FIGS. 1-11 show cross-sectional views of a light-emitting device 10′ during the manufacturing process, in accordance with some embodiments of the present disclosure. FIG. 12 shows a cross-sectional view of the light-emitting device 10′, in accordance with some embodiments of the present disclosure.

Referring to FIG. 12, the light-emitting device 10′ includes a control part 10C and a light-emitting part 10L. The control part 10C includes a first semiconductor stack 110′ having a two-dimensional electron gas (not shown) therein. The light-emitting part 10L includes a second semiconductor stack 120′. The light-emitting device 10′ further includes: a first electrode 172 electrically connecting the control part 10C and the light-emitting part 10L; and a second electrode 152 electrically connecting the control part 10C and the light-emitting part 10L, wherein the control part 10C and the light-emitting part 10L are electrically connected in parallel through the first electrode 172 and the second electrode 152. The manufacturing process of the light-emitting device 10′ is described in detail as the following.

Referring to FIG. 1, a semiconductor structure 10 including a substrate 100, a first semiconductor stack 110 and a second semiconductor stack 120 is provided first. The following figures show the semiconductor structure 10 in corresponding processes for forming the light-emitting device 10′. For brevity, the incomplete light-emitting device 10′ in each step of the manufacturing processes shown in each figures is also named semiconductor structure 10. In one embodiment, the semiconductor structure 10 including the first semiconductor stack 110 and the second semiconductor stack 120 is provided. In another embodiment, a semiconductor structure including the first semiconductor stack 110 is provided first, and then the second semiconductor stack 120 is formed on the first semiconductor stack 110.

In some embodiments, the substrate 100 is a semiconductor substrate or an insulating substrate. The material of the insulating substrate includes sapphire. The materials of the semiconductor substrate include elemental semiconductors, such as silicon or germanium; or compound semiconductors, such as silicon carbide, gallium nitride, aluminum nitride, aluminum gallium nitride, or combinations thereof. The substrate 100 can be a multi-layered substrate, such as a silicon-on-insulator (SOI) substrate. Although not shown, a nucleation layer may also be formed on the substrate 100 to improve the epitaxial quality of subsequently formed layers (e.g., the buffer layer 102 or the first semiconductor stack 110).

As shown in FIG. 1, according to some embodiments of the present disclosure, a buffer layer 102 is formed between the substrate 100 and the first semiconductor stack 110. The strain caused by the lattice mismatch between the substrate 100 and the first semiconductor stack 110 can be relieved by the buffer layer 102, so as to prevent defects from being formed in the first semiconductor stack 110. In some embodiments, the material of the buffer layer 102 includes aluminum nitride (AlN), gallium nitride (GaN), aluminum gallium nitride (AlGaN), other suitable materials, or a combination thereof. In addition, the buffer layer 102 may be formed by an epitaxial growth process, such as a metal-organic chemical vapor deposition (MOCVD) process, a hydride vapor phase epitaxy (HYPE) process, a molecular beam epitaxy (MBE) process, other suitable processes, or a combination thereof. The thickness of the buffer layer 102 may be between 0.3 μm and 30 μm, for example, 5 μm, but the present disclosure is not limited thereto. It should be understood that although the buffer layer 102 in FIG. 1 is shown as a single-layered structure, the buffer layer 102 may also have a multi-layered structure in accordance with other embodiments.

The first semiconductor stack 110 includes a channel layer 112 and a barrier layer 114. In some embodiments, the material of the channel layer 112 has a first energy bandgap and a first lattice constant, and the material of the barrier layer 114 has a second energy bandgap and a second lattice constant. The second energy bandgap is greater than the first energy bandgap, and the first lattice constant is different from (e.g., greater than) the second lattice constant. The two-dimensional electron gas (2 DEG) (not shown in FIG. 1) may be formed near the heterojunction between the channel layer 112 and the barrier layer 114. In this embodiment, the two-dimensional electron gas is formed in the channel layer 112. According to some embodiments, a portion of the subsequently formed light-emitting device (e.g., the light-emitting device 10′ in FIG. 12) is a high-electron mobility transistor (e.g., the control part 10C) using the two-dimensional electron gas (2DEG) as conductive carriers. Materials of the channel layer 112 and the barrier layer 114 include III-V compound semiconductors, such as III nitrides. III nitrides include InₓAl_{y}Ga_{1-(x+y)}N, where 0≤x≤1, 0≤y≤1, x+y≤1, such as gallium nitride (GaN), aluminum nitride (AlN), aluminum gallium nitride (AlGaN), indium aluminum nitride (InAlN), indium gallium Nitride (InGaN), indium aluminum gallium nitride (InAlGaN), or a combination thereof. The materials of the channel layer 112 and the barrier layer 114 may or may not have dopant. The dopant may be an n-type dopant or a p-type dopant. In addition, the channel layer 112 and the barrier layer 114 may be formed by an epitaxial growth process, such as metal organic chemical vapor deposition (MOCVD) process, hydride vapor phase epitaxy (HVPE) process, molecular beam epitaxy (MBE) process, other suitable methods, or a combination thereof.

In some embodiments, the thickness of the channel layer 112 may be between 20 nm and 30 nm, but the present disclosure is not limited thereto. In some embodiments, the thickness of the barrier layer 114 may be between 200 nm and 350 nm, but the present disclosure is not limited thereto.

The second semiconductor stack 120 may include a first contact layer 122, a second contact layer 124 disposed above the first contact layer 122, and a light-emitting layer 126 disposed between the first contact layer 122 and the second contact layer 124. The first contact layer 122 and the second contact layer 124 have different dopants with different polarities to provide electrons and holes, respectively. The electrons and holes provided by the first contact layer 122 and the second contact layer 124 can recombine in the light-emitting layer 126 to generate light. For example, the first contact layer 122 may be an n-type semiconductor layer, and the second contact layer 124 may be a p-type semiconductor layer. The material of the second semiconductor stack 120 includes III-V semiconductors, such as AlₓIn_{y}Ga_{(1-x-y)}N or AlₓIn_{y}Ga_{(1-x-y)}P, where 0≤x, y≤1, (x+y)≤1. When the material of the second semiconductor stack 120 includes AlInGaP series material, it can emit red light with wavelengths between 610 nm and 650 nm or green light with wavelengths between 530 nm and 570 nm. When the material of the second semiconductor stack 120 includes InGaN series material, it can emit blue light with wavelengths between 400 nm and 490 nm, or green light with wavelengths between 530 nm and 570 nm. When the material of the second semiconductor stack 120 includes AlGaN or AlGaInN series material, it can emit ultraviolet light with a wavelength between 250 nm and 400 nm. The structure of the light-emitting layer 126 may include a single heterostructure (SH), a double heterostructure (DH), a double-side double heterostructure (DDH), or a multi-quantum well (MQW) structure. The material of the light-emitting layer 126 may be an undoped semiconductor, a p-type doped semiconductor, or a n-type doped semiconductor.

In addition, each layer of the second semiconductor stack 120 may be formed by an epitaxial growth process, such as metal organic chemical vapor deposition (MOCVD) process, hydride vapor phase epitaxy (HVPE) process, molecular beam epitaxy (MBE) process, other suitable methods, or a combination thereof.

Referring to FIG. 2, a portion of the second semiconductor stack 120 is removed to form second semiconductor stacks 120′ and the recess 130 between the second semiconductor stacks 120′ in this step. The recess 130 exposes a top surface of the first semiconductor stack 110. In other words, the bottom surface of the recess 130 includes a portion of the top surface of the first semiconductor stack 110. The recess 130 may divide the semiconductor structure 10 into a predetermined control area 130C and a predetermined light-emitting area 130L. The predetermined control area 130C corresponds to the portion of the first semiconductor stack 110 under the recess 130, and the predetermined light-emitting area 130L corresponds to the second semiconductor stack 120′.

The above-mentioned process for removing a portion of the second semiconductor stack 120 may include a dry etching process, a wet etching process, and/or other suitable processes. The dry etching process may include plasma etching, inductively coupled plasma (ICP) etching, reactive ion etching (ME), or a combination thereof. The wet etching process is performed in, for example, acid solution such as diluted hydrofluoric acid (DHF), hydrofluoric acid (HF) solution, nitric acid (HNO₃), and/or acetic acid (CH₃COOH); alkaline solution such as potassium hydroxide (KOH) solution and/or ammonia; or other suitable wet etchants by dipping, spraying, or the like.

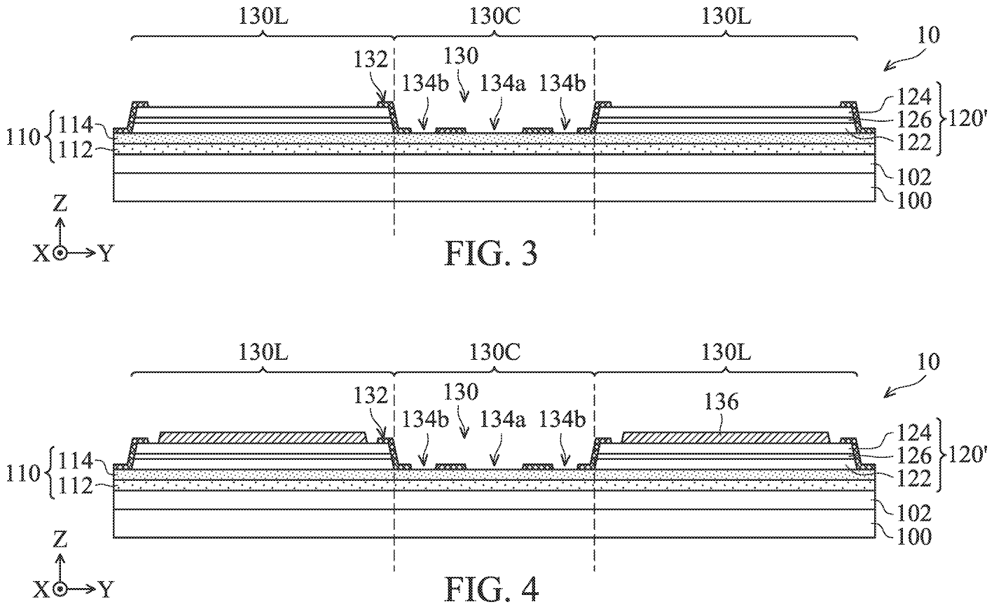

Referring to FIG. 3, after forming the recess 130, a protective layer 132 is formed on the side surfaces and the bottom surface of the recess 130 in accordance with some embodiments. As a result, the protective layer 132 can be used to protect the side surfaces of the second semiconductor stack 120′ in subsequent processes. In some embodiments, the protective layer 132 is formed of dielectric material, including organic material such as a photoresist (e.g., Su8), benzocyclobutene (BCB), perfluorocyclobutane (PFCB), epoxy, acrylic resin, cyclic olefin copolymer (COC), polymethyl methacrylate (PMMA), polyethylene terephthalate (PET), polycarbonate (PC), polyetherimide, or fluorocarbon polymer. The protective layer 132 may also include inorganic material, such as silicone, glass, alumina (Al₂O₃), silicon nitride (SiNₓ), silicon oxide (SiOₓ), titanium oxide (TiOₓ), or magnesium fluoride (MgFₓ). In addition, the formation of the protective layer 132 includes patterning the material for the protective layer 132 by lithography and/or etching process. The lithography process may include photoresist coating (e.g., spin coating), soft baking, mask alignment, exposure, post-exposure bake, photoresist development, rinsing, drying (e.g., spin-drying) and/or hard baking, other suitable lithography techniques, and/or combinations thereof. The etching process may include dry etching (e.g., RIE etching), wet etching, and/or other etching method. After the above patterning process, the protective layer 132 has a first opening 134a and a plurality of second openings 134b, and another opening on the top surface of the second semiconductor stack 120′, so that the top surface of the second semiconductor stack 120′ is exposed by this opening of the protective layer 132. In addition, the first opening 134a and the second opening 134b expose at least a portion of the first semiconductor stack 110 at the bottom surface of the recess 130.

Referring to FIG. 4, a conductive layer 136 is formed on the exposed top surface of the second semiconductor stack 120′. The conductive layer 136 can also be used as a reflective layer to control the light-emitting direction of the light-emitting device, and the position and the size of the conductive layer 136 may be adjusted according to the light-emission position in the completed light-emitting device. The material of the conductive layer 136 may include metal materials with high reflectivity, such as silver (Ag), aluminum (Al), gold (Au), titanium (Ti), copper (Cu), platinum (Pt), nickel (Ni), rhodium (Rh), or an alloy thereof. The “high reflectivity” mentioned herein refers to a reflectivity of more than 80% for the wavelength of the light emitted by the light-emitting layer 126. In addition, the conductive layer 136 may be formed by physical vapor deposition (PVD), chemical vapor deposition (CVD), atomic layer deposition (ALD), other suitable processes, or a combination thereof.

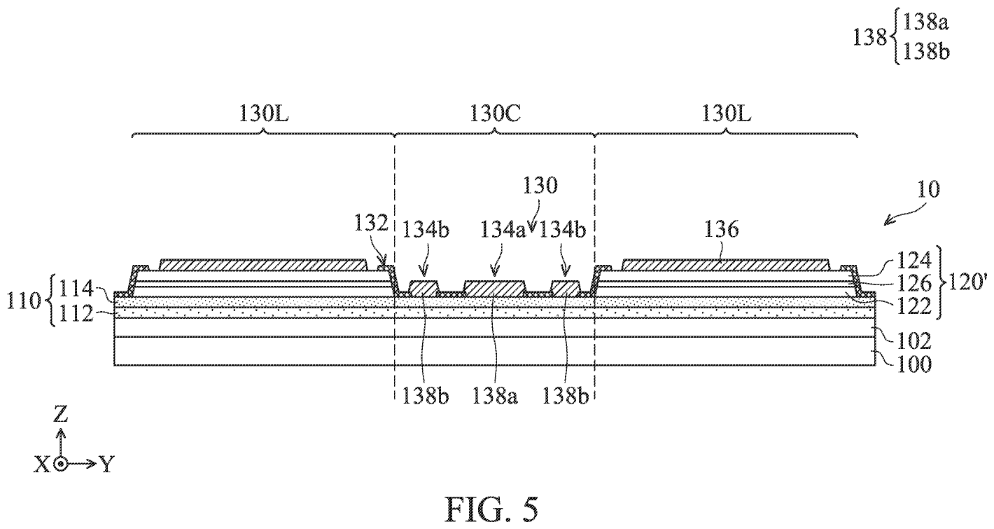

Please refer to FIG. 5. At this stage, metal components 138 including metal components 138a, 138b are formed in the recess 130. At least part of the metal component 138a fills the first opening 134a, and at least part of the metal components 138b fill each of the second openings 134b. The metal component 138 includes metal material such as chromium (Cr), titanium (Ti), tungsten (W), aluminum, indium (In), tin (Sn), nickel (Ni), platinum (Pt), other suitable materials, or a combination thereof. The metal components 138a, 138b may include the same material or different materials. Additionally, the metal component 138 may be formed by physical vapor deposition (PVD), chemical vapor deposition (CVD), atomic layer deposition (ALD), electroplating, other suitable processes, or a combination thereof. When the process temperatures of the conductive layer 136 and the metal components 138 are different, the conductive layer 136 and the metal components 138 are formed in order of the formation temperatures thereof. In order to avoid that the process temperature of the later-formed film is too high and causes the previously-formed film to melt or be damaged, the film with a higher process temperature may be fabricated first. For example, if the highest process temperature (e.g., about 700° C.) of the conductive layer 136 is greater than the highest process temperature of the metal components 138 (e.g., about 600° C.), the conductive layer 136 may be formed before forming the metal components 138.

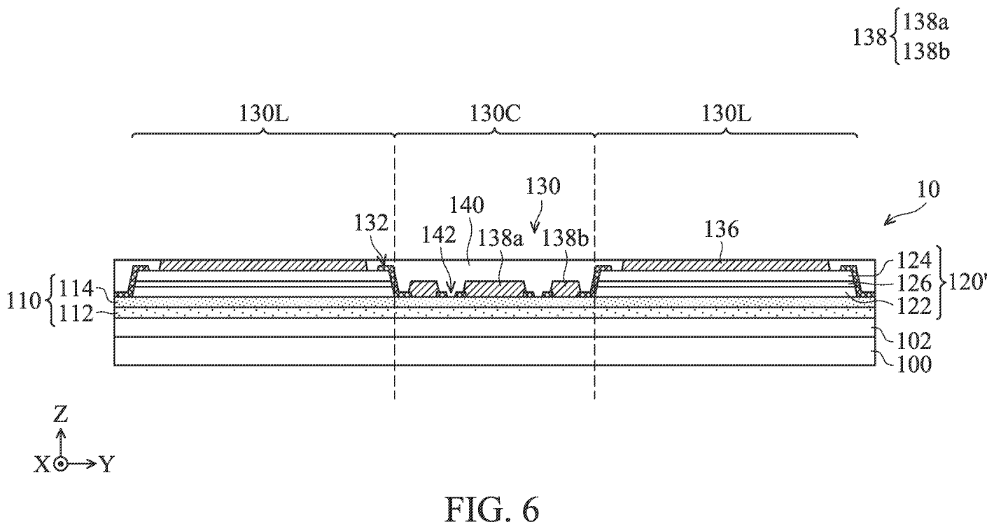

Referring to FIG. 6, a current blocking layer 140 is formed on the semiconductor structure 10. In some embodiments, the current blocking layer 140 is filled in the recess 130 and is located between the metal components 138a and 138b. The current blocking layer 140 connects the first semiconductor stack 110 and the second semiconductor stack 120′. In this embodiment, before forming the current blocking layer 140, the protective layer 132 in the recess 130 is etched to form a plurality of third openings 142. The method for etching the protective layer 132 to form the third openings 142 is similar to the etching process for patterning the protective layer 132 described above, and the detailed description thereof is omitted for brevity.

The material of the current blocking layer 140 can be selected to be suitable for filling the recess 130, including, for example, tetraethylorthosilicate (TEOS) oxide, undoped silicate glass, or doped silicon oxide, such as borophosphosilicate glass (BPSG), fused silica glass (FSG), phosphosilicate glass (PSG), boron doped silicon glass (BSG), and/or other suitable dielectric materials. The current blocking layer 140 may be formed by depositing materials of the current blocking layer 140 via spin-on-glass (SOG), plating or other suitable processes to. Next, in order to remove parts of the material of the current blocking layer 140 and expose the top surface of the conductive layer 136, a planarization process such as a chemical mechanical polishing (CMP) may be performed, so that the top surfaces of the current blocking layer 140 and the conductive layer 136 are substantially leveled.

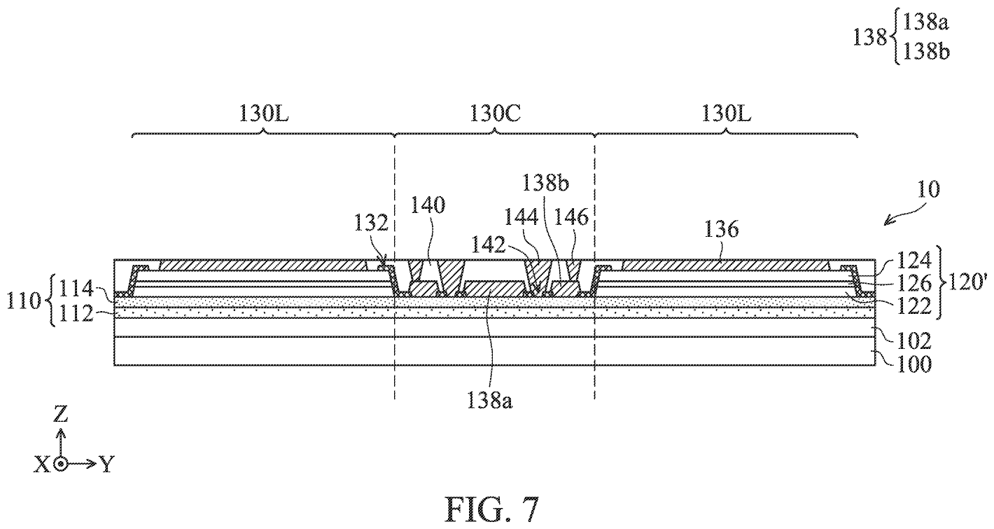

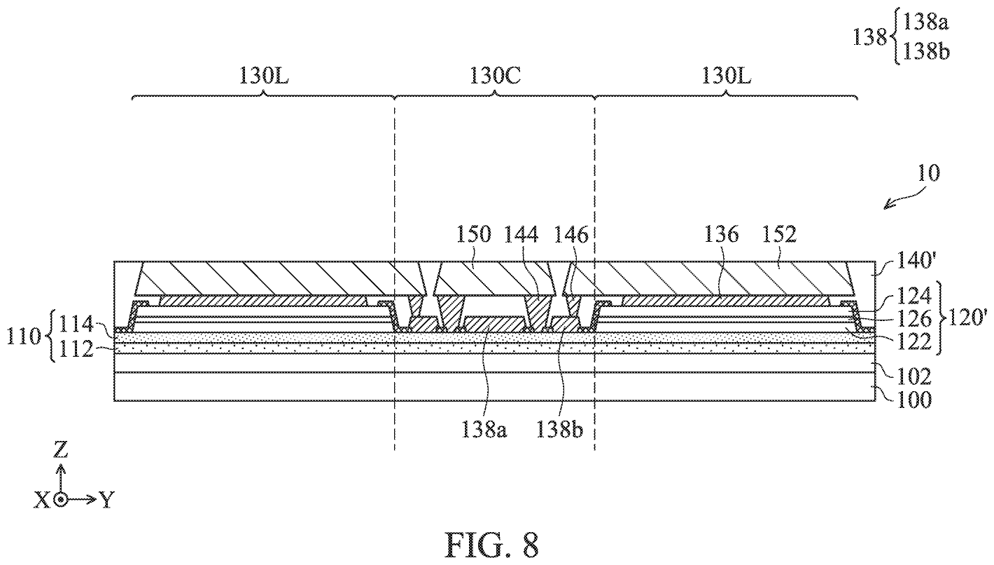

Referring to FIG. 7, a third conductive channel 144 and a second conductive channel 146 are formed in the current blocking layer 140. As shown in FIG. 7, the conductive material of the third conductive channel 144 is filled in the third opening 142 and electrically connected to the first semiconductor stack 110, and the conductive material of the second conductive channel 146 is electrically connected to a part of the metal component 138b. The third conductive channel 144 and the second conductive channel 146 may include, for example, copper, tungsten, titanium, titanium nitride, aluminum, ruthenium, molybdenum, cobalt, other suitable conductive materials, or a combination thereof. In addition, the formation of the third conductive channel 144 and the second conductive channel 146 may include removing a part of the material of the current blocking layer 140 by using lithography and etching processes. Then, one or more of the conductive materials mentioned above is deposited in the opening left after removing the material of the part of the current blocking layer 140. After depositing the conductive materials for the third conductive channel 144 and the second conductive channel 146, the excess conductive material may be removed by a suitable etch back process or a planarization process. As a result, the top surfaces of the third conductive channel 144 and the second conductive channel 146 may be substantially leveled with the top surface of the current blocking layer 140.

Please refer to FIG. 8. After the third conductive channel 144 and the second conductive channel 146 are formed, a third electrode 150 is formed on the third conductive channel 144 and the current blocking layer 140 by suitable deposition and patterning processes, and a second electrode 152 is formed on the second conductive channel 146 and the current blocking layer 140. In some embodiments, the conductive layer 136 is located between the second electrode 152 and the second semiconductor stack 12′. The materials of the third electrode 150 and the second electrode 152 may include conductive material, such as metal, metal compound, or a combination thereof. For example, the metal material include gold, nickel, platinum, palladium, iridium, titanium, chromium, tungsten, aluminum, copper, silver, an alloy, a laminated stack, or a combination of the above materials. The metal compound includes titanium nitride. In some embodiments, the third electrode 150 is formed of a metal or a metal compound having a work function greater than 4.5 eV. In addition, the methods of forming the third electrode 150 and the second electrode 152 may be substantially the same. The methods of forming the third electrode 150 and the second electrode 152 may include physical vapor deposition (PVD), chemical vapor deposition (CVD), atomic layer deposition (ALD), electron-beam evaporation, electroplating, other suitable methods, or a combination thereof.

As shown in FIG. 8, the third electrode 150 is electrically connected to the first semiconductor stack 110 through the third conductive channel 144, so the third electrode 150 may be electrically connected to the control part of the subsequently formed light-emitting device. The second electrode 152 is electrically connected to the first semiconductor stack 110 through the second conductive channel 146 and the metal component 138b, and may also be electrically connected to the second semiconductor stack 120′ through the conductive layer 136. Therefore, the second electrode 152 may be electrically connected to the control part and the light-emitting part of the subsequently formed light-emitting device. A Schottky barrier is formed between the third electrode 150 and the first semiconductor stack 110, and the second electrode 152 forms an ohmic contact with the first semiconductor stack 110 through the second conductive channel 146.

After the third electrode 150 and the second electrode 152 are formed, a material similar to the current blocking layer 140 may be deposited on the semiconductor structure 10 to form the current blocking layer 140′. The current blocking layer 140′ includes the material of the previously formed current blocking layer 140 and a similar material deposited on current blocking layer 140. In some embodiments, the current blocking layer 140′ fills the periphery of the second electrode 152 and the space between the third electrode 150 and the second electrode 152. Since the material and the method of forming the current blocking layer 140′ are similar to those of the current blocking layer 140, the detailed description thereof is omitted here for brevity. Next, in order to remove parts of the materials of the current blocking layer 140′ and expose the top surfaces of the third electrode 150 and the second electrode 152, a planarization process such as a chemical mechanical polishing (CMP) process may be performed, so that the top surfaces of the current blocking layer 140, the third electrode 150 and the second electrode 152 are substantially leveled.

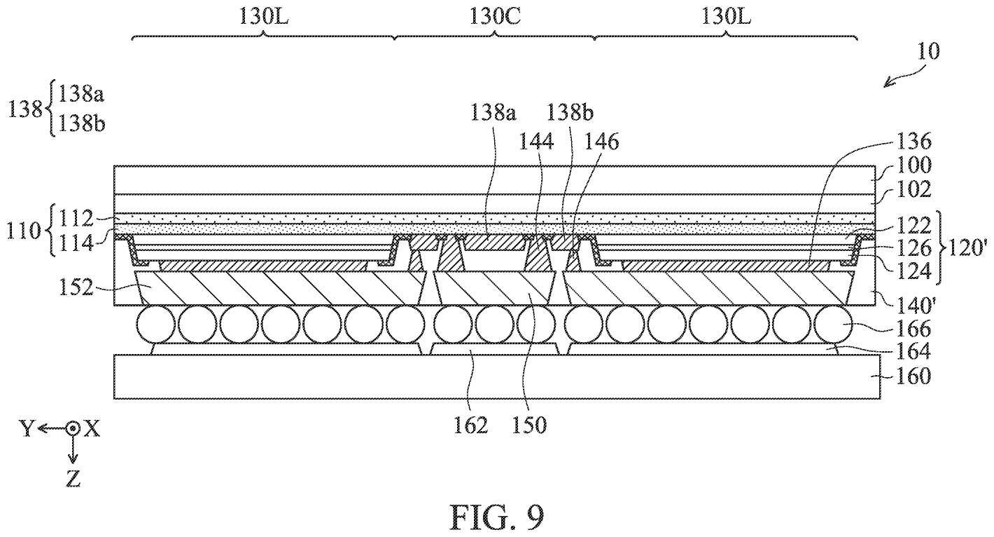

Referring to FIG. 9, after the current blocking layer 140′ is formed, the semiconductor structure 10 is reversed so that the top surfaces of the third electrode 150 and the second electrode 152 face downward. In some embodiments, a second substrate 160 such as a circuit board is further provided, and the second substrate 160 has a first bonding portion 162 for electrically connecting the third electrode 150 and a second bonding portions 164 for electrically connecting the second electrodes 152. Next, soldering portions 166 are formed on the first bonding portion 162 and the second bonding portion 164 and/or on the semiconductor structure 10 to bond the semiconductor structure 10 to the second substrate 160. The material of the first bonding portion 162 and the second bonding portion 164 may include metal, such as Au/Sn, Al/Cu or Ti/Al, or a glue material mixed with metal particles, such as anisotropic conductive glue. The above-mentioned bonding step may be performed using a bonding process known in the art, for example, the soldering portions 166 including tin are welded between the third electrode 150 and the first bonding portion 162 and between the second electrode 152 and the second bonding portion 164.

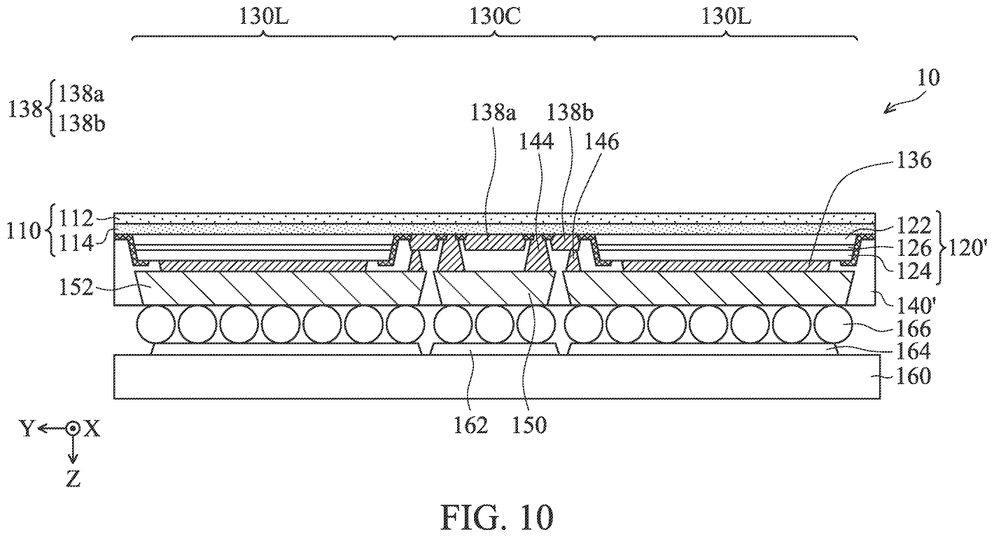

Referring to FIG. 10, the substrate 100 is removed. The method for removing the substrate 100 includes, for example, laser lift-off, or etching, such as dry etching or wet etching. During the laser lift-off process for removing the substrate 100 and the buffer layer 102 from the first semiconductor stack 110, the gallium nitride material of the semiconductor structure 10 absorbs the laser energy, and Ga and N2 are formed, which causes molecular decomposition at the interface between the first semiconductor stack 110 and the substrate 100 and the buffer layer 102. As a result, the substrate 100 and the buffer layer 102 are removed. In one embodiment, in the laser lift-off process, the laser irradiates the semiconductor structure 10 and further provides thermal energy to the soldering portions 166 for fixing the semiconductor structure on the second substrate 160.

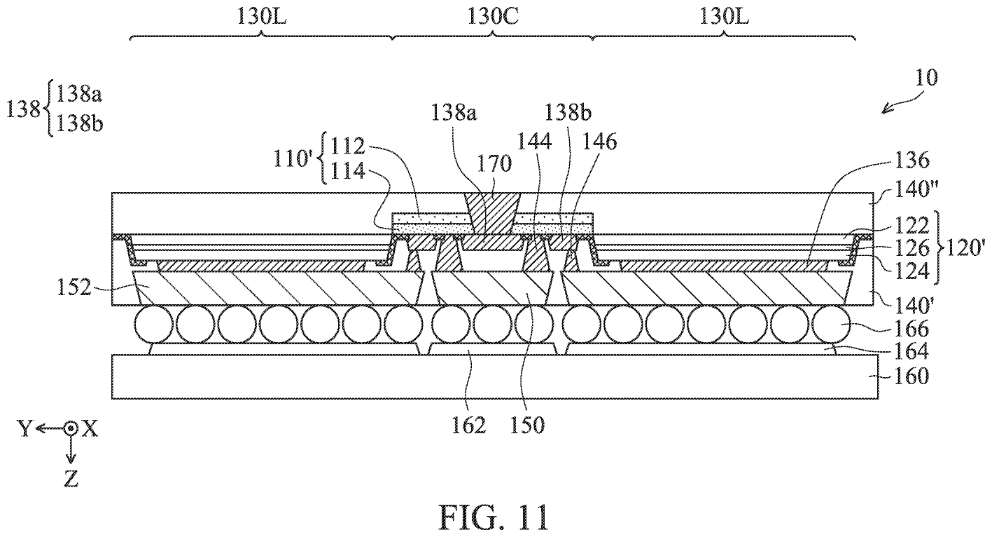

Referring to FIG. 11, after the substrate 100 and the buffer layer 102 are removed, the first semiconductor stack 110 located on the predetermined light-emitting area 130L may be removed to form the first semiconductor stack 110′ (i.e. the remaining portion of the first semiconductor stack 110). After the removal process, the first semiconductor stack 110′ and the second semiconductor stack 120′ do not overlap in the vertical direction (Z direction in FIG. 11). In one embodiment, the first semiconductor stack 110′ and the second semiconductor stack 120′ do not overlap in the vertical direction, and the second semiconductor stack 120′ is not in physical contact with the first semiconductor stack 110′.

Next, a current blocking layer 140″ is formed on the first semiconductor stack 110′ and the second semiconductor stack 120′ to cover the first semiconductor stack 110′ and the second semiconductor stack 120′. The current blocking layer 140″ may include similar materials as those of the previously formed current blocking layer 140 or current blocking layer 140′. Since the material and forming method of the current blocking layer 140″ are similar to those of the current blocking layer 140 or the current blocking layer 140′, the detailed description thereof is omitted here for brevity.

Next, as shown in FIG. 11, after the current blocking layer 140″ is formed, a first conductive channel 170 may be formed in the current blocking layer 140″ and the first semiconductor stack 110′. The material of the first conductive channel 170 may be similar to that of the third conductive channel 144 and the second conductive channel 146, which includes, for example, copper, tungsten, titanium, titanium nitride, aluminum, ruthenium, molybdenum, cobalt, other suitable conductive materials, or combinations thereof. The formation of the first conductive channe1170 includes removing a portion of the current blocking layer 140″ and a portion of the first semiconductor stack 110′ by lithography process and etching process. Then, one or more of the aforementioned conductive materials is deposited in the openings remained after removing a portion of the current blocking layer 140″ and a portion of the first semiconductor stack 110′. The conductive material of the first conductive channe170 may be filled in the above-mentioned openings and penetrate through the first semiconductor stack 110′, and be electrically connected to the first semiconductor stack 110′ through the corresponding metal component 138a. In addition, after depositing the material for the first conductive channel 170, an appropriate etch-back process or planarization process may be applied, so that the top surface of the first conductive channe1170 may be substantially leveled with the top surface of the current blocking layer 140″. In another embodiment, a dielectric layer (not shown) is formed between the conductive material of the first conductive channel 170 and the first semiconductor stack 110′ to electrically isolate the conductive material and the first semiconductor stack 110′.

Referring to FIG. 12, after the first conductive channe1170 is formed, a first electrode 172 is formed on the first conductive channel 170. As shown in FIG. 12, in some embodiments, the first electrode 172 is electrically connected to the first semiconductor stack 110′ through the first conductive channe1170 and the corresponding metal component 138a, and the first electrode 172 penetrates the current blocking layer 140″ to electrically connect to the second semiconductor stack 120′. In some embodiments, the first electrode 172 and the second electrode 152 are located on opposite sides of the second semiconductor stack 120′ in the vertical direction. The material and formation method of the first electrode 172 may be similar to those of the third electrode 150 and the second electrode 152, and are not described in detail here for the sake of brevity. In addition, the method for forming the first electrode 172 may include removing a portion of the material of the current blocking layer 140″ on the second semiconductor stack 120′ by lithography and etching processes, followed by depositing a conductive material in the opening left after removing the material of the portion of the current blocking layer 140″. The first electrode 172 may be filled in the above-mentioned openings and penetrates the current blocking layer 140″, thereby electrically connecting the second semiconductor stack 120′.

After the aforementioned manufacturing processes, the light-emitting device 10′ is completed. The light-emitting device 10′ includes the light-emitting part 10L for emitting light and the control part 10C for controlling the light-emitting part 10L. As shown in FIG. 12, the control part 10C and the light-emitting part 10L are electrically connected in parallel via the first electrode 172 and the second electrode 152. In some embodiments, the first semiconductor stack 110′ in the control part 10C can be equivalent to an epitaxial stack of a high electron mobility transistor. In this embodiment, the second semiconductor stack 120′ in the light-emitting portion 10L can be equivalent to an epitaxial stack of light-emitting diodes. In addition, in some embodiments, the control part 10C further includes the third conductive channel 144 and the second conductive channel 146, and the second electrode 152 and the third electrode 150 are electrically connected to the first semiconductor stack 110′ through the second conductive channel 146 and the third conductive channel 144, respectively. In one embodiment, the third conductive channel 144 is a gate conductive channel, the third electrode 150 is a gate pad. A control voltage is applied on the third electrode 150 (gate pad) to the control part 10C through the third conductive channel 144 (gate conductive channel), so that the two-dimensional electron gas in the first semiconductor stack 110′ is depleted to form an open circuit or conducted to form a current path, and the light-emitting part 10L is controlled to be turned on by the conducting in the control part 10C or off by the open circuit in the control part 10C. In one embodiment, from the top view (not shown), the light-emitting part 10L is in a closed or non-closed annular shape, and surrounds the control part 10C. In another embodiment, the light-emitting part 10L includes a plurality of discrete portions, which are respectively located on both sides of the control part 10C.

Depending on the doping type of the first contact layer 122 and the second contact layer 124 in the second semiconductor stack 120′, the metal components 138a, 138b may be regarded as a portion of the source or the drain of the high electron mobility transistor, respectively, or may be regarded as the source or the drain of the high electron mobility transistor, respectively. The third conductive channel 144 may be regarded as a portion of the gate of the high electron mobility transistor, or may be regarded as the gate of the high electron mobility transistor, respectively. The way of interpretation is not limited here. In this embodiment, the first contact layer 122 is an n-type semiconductor layer and the second contact layer 124 is a p-type semiconductor layer, the metal component 138a may be regarded as the source of the high electron mobility transistor, and the metal component 138b may be regarded as the drain of the high electron mobility transistor. The first electrode 172 is electrically connected between the metal component 138a (source) and the first semiconductor layer 122, and the second electrode 152 is electrically connected between the metal component 138b (drain) and the second semiconductor layer 124.

In control methods of light-emitting diodes, one is connecting a light-emitting diode to a plurality of metal-oxide-semiconductor (MOS) transistors in an external manner, and an external capacitor is connected in a series circuit to realize the control of light-emitting diodes. Complicated manufacturing processes are required to form the above circuit. Also, an integrated manufacturing process of the silicon-based MOS transistor and the gallium nitride-based light-emitting diode is difficult to be realized, resulting in higher manufacturing costs, poorer component accuracy and low yield. In contrast, in the present disclosure, by integrating the manufacturing processes of the control part and the light-emitting part of the light-emitting device, the switching of the light-emitting diode in the light-emitting device can be controlled even without external capacitors. As a result, the manufacturing process in accordance with the present disclosure simplifies the manufacturing process of the light-emitting device, thereby reducing the manufacturing cost, benefits the miniaturization of the light-emitting devices in an array and improves the precision of the light-emitting device. Since the driving signal of the light-emitting device in accordance of the present disclosure does not need to transmitted through a silicon-based MOS transistor, the light-emitting device can have a higher response speed. In addition, since the high electron mobility transistor including gallium nitride is used as the control part of the light-emitting device in the present disclosure, it can achieve good integration with the gallium nitride-based light-emitting diode, thereby improving the yield of the light-emitting device.

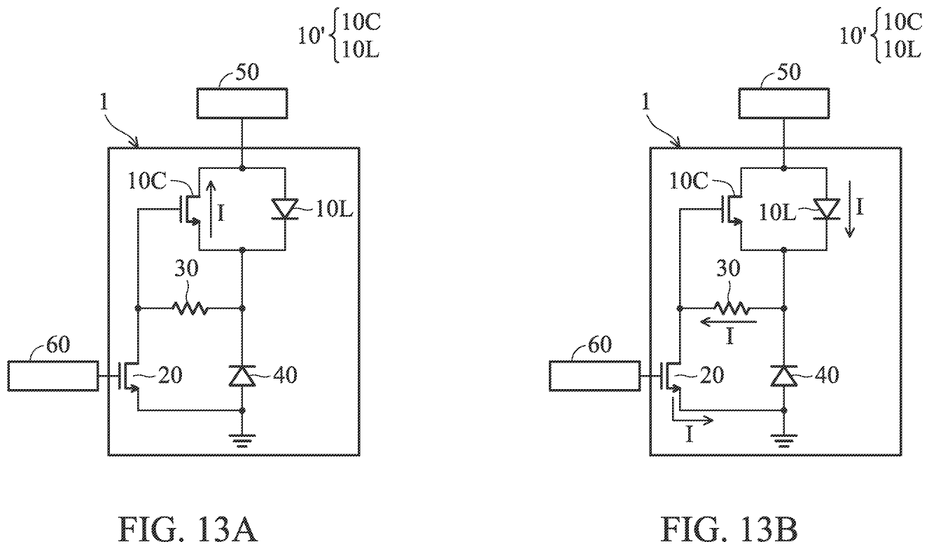

FIGS. 13A and 13B are schematic diagrams showing exemplary light-emitting circuits in accordance with to some embodiments of the present disclosure. Referring to FIGS. 13A and 13B, the light-emitting circuit 1 includes: the light-emitting device 10′, a transistor 20 coupled to the light-emitting device 10′, and a resistor 30 coupled between the light-emitting device 10′ and the transistor 20, and a diode 40 that couples the light-emitting device 10″ and the resistor 20. The transistor 20 can receive driving signals from other signal sources (e.g., the second signal source 60), and is selectively turned on according to the driving signals. The resistor 30 is used to provide a potential difference between the light-emitting device 10′ and the transistor 20 so that the control part 10C does not generate leakage currents in an off-state. It should be noted that the conduction direction of the diode 40 is opposite to that of the light-emitting part 10L of the light-emitting device 10′, thereby preventing leakage currents.

In the light-emitting circuit 1, the operation thereof is described as follows. Referring to FIG. 13A, when the transistor 20 is turned-off, the control part 10C is in a conducting state, and no current flows through the light-emitting part 10L. Referring to FIG. 13B, when the transistor 20 is turned-on, the control part 10C is in a non-conducting state, and the current I flows through the light-emitting part 10L, the resistor 30, and the transistor 20. In some embodiments, the light-emitting circuit 1 is electrically connected to a first signal source 50 providing a bias to the light-emitting device 10′ and/or a second signal source 60 providing a driving signal to the transistor 20. In some embodiments, in a light-emitting array (not shown) including a plurality of light-emitting circuits 1, the second signal source 60 has a plurality of output terminals (not shown in FIGS. 13A and 13B) that are electrically connected to a plurality of transistors 20, respectively. The transistors 20 are used to control these light-emitting circuits 1, respectively. For example, the second signal source 60 can control the transistor 20 of one of the light-emitting circuits 1, so as to control the corresponding light-emitting part 10L to emit light or not to emit light, thereby achieving addressing control. However, the present disclosure is not limited to this, and those with ordinary skill in the art of the present disclosure may use other types of circuits or add other elements to the light-emitting circuit as required, thereby using other control methods to control the light-emitting device.

In summary, the present disclosure provides a light-emitting device and a light-emitting circuit including the light-emitting device. Considering that the light-emitting diode is driven by current, the manufacturing method of the light-emitting device of the present disclosure integrates the formation of a high electron mobility transistor into the manufacturing process of the light-emitting diode, and the driving mode of the light-emitting diode is controlled by the switching of the transistor. In addition, since the high electron mobility transistor is a high-speed transistor made of group III-V compounds, it has good bonding with the light-emitting diode and does not slow down the response of the light-emitting diode. As a result, compared with the conventional manufacturing process, which may result in poor yield due to the difference in precision when combining light-emitting diodes and transistors, the light-emitting device of the present disclosure integrates the driving and the controlling elements with the light-emitting diodes via electrically-parallel connection. Thereby, while improving the efficiency of the light-emitting device, the yield of the light-emitting device is improved and the manufacturing cost thereof is reduced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting device, comprising:
a control part comprising a first semiconductor stack having a two-dimensional electron gas therein;
a light-emitting part comprising a second semiconductor stack;
a first electrode electrically connecting the control part and the light-emitting part; and
a second electrode electrically connecting the control part and the light-emitting part,
wherein the control part and the light-emitting part are electrically connected in parallel through the first electrode and the second electrode.

2. The light-emitting device of claim 1, wherein the control part comprises a first conductive channel penetrating through the first semiconductor stack, and the first electrode is on an upper surface of the first semiconductor stack.

3. The light-emitting device of claim 2, further comprising a metal component located on a lower surface of the first semiconductor stack opposite to the first electrode and, wherein the metal component is electrically connected to the first semiconductor stack.

4. The light-emitting device of claim 3, wherein the first electrode is electrically connected to the first semiconductor stack through the first conductive channel and the metal component.

5. The light-emitting device of claim 1, wherein the light-emitting part further comprises a conductive layer between the second electrode and the second semiconductor stack.

6. The light-emitting device of claim 1, wherein the first semiconductor stack is not in physical contact with the second semiconductor stack.

7. The light-emitting device of claim 1, wherein the first semiconductor stack comprises:
a channel layer; and
a barrier layer under the channel layer,
wherein the two-dimensional electron gas is in the channel layer and close to an interface between the barrier layer and the channel layer.

8. The light-emitting device of claim 1, wherein the second semiconductor stack comprises:
a first contact layer;
a second contact layer disposed below the first semiconductor stack; and
a light-emitting layer disposed between the first contact layer and the second contact layer.

9. The light-emitting device of claim 8, wherein the light-emitting layer comprises a multi-quantum well.

10. The light-emitting device of claim 1, further comprising a protection layer on a lower surface of the first semiconductor stack and on a side surface of the second semiconductor stack, and the protection layer exposes at least a portion of the first semiconductor stack.

11. The light-emitting device of claim 1, further comprising a third electrode, wherein the control part further comprises a second conductive channel and a third conductive channel, and the second electrode and the third electrode are electrically connected to the control part through the second conductive channel and the third conductive channel, respectively.

12. The light-emitting device of claim 11, further comprising a current blocking layer between the second conductive channel and the third conductive channel.

13. A method for manufacturing a light-emitting device, comprising:
providing a substrate with a first semiconductor stack and a second semiconductor stack sequentially formed thereon;
removing the second semiconductor stack on a first predetermined region;
forming a current blocking layer on the first predetermined region;
forming a second electrode on the first semiconductor stack and the second semiconductor stack, wherein the second electrode electrically connects the first semiconductor stack and the second semiconductor stack;
removing the substrate;
removing the first semiconductor stack corresponding to a second predetermined region; and
forming a first electrode on the first semiconductor stack and the second semiconductor stack, wherein the first electrode electrically connects the first semiconductor stack and the second semiconductor stack,
wherein the first semiconductor stack and the second semiconductor stack are electrically connected in parallel through the first electrode and the second electrode.

14. The method for manufacturing the light-emitting device of claim 13, further comprising forming a first conductive channel penetrating through the first semiconductor stack, wherein the first electrode is electrically connected to the first conductive channel through the first electrode.

15. The method for manufacturing the light-emitting device of claim 13, further comprising forming a conductive layer on the second semiconductor stack.

16. The method for manufacturing the light-emitting device of claim 13, wherein the first semiconductor stack comprises a barrier layer and a channel layer disposed on the barrier layer; and wherein the second semiconductor stack comprises a first contact layer; a second contact layer disposed above the first contact layer; and a light-emitting layer disposed between the first contact layer and the second contact layer.

17. The method for manufacturing the light-emitting device of claim 13, wherein removing the second semiconductor stack of the first predetermined region comprises forming a recess, and the recess exposes a top surface of the first semiconductor stack.

18. The method for manufacturing the light-emitting device of claim 17, further comprising forming a protection layer on a side surface and a bottom surface of the recess, and the protection layer exposes at least a portion of the first semiconductor stack.

19. The method for manufacturing the light-emitting device of claim 17, further comprising forming a third conductive channel and a second conductive channel in the recess.

20. A light-emitting circuit, comprising:
the light-emitting device of claim 1;
a transistor coupled to the light-emitting device for accepting a driving signal, wherein the transistor is selectively conducting according to the driving signal;
a resistor coupled between the light-emitting device and the transistor; and
a diode coupling the light-emitting device and the resistor, wherein a conduction direction of the diode is contrary to a conduction direction of the light-emitting part;
wherein the control part is in a conducting state when the transistor is turned-off, and wherein the control part is in a non-conducting state when the transistor is turned-on with a current passing through the light-emitting part and the resistor.
